(19) United States
(12) Patent Application Publication
(10) Pub. No.: US 2026/0262453 A1
(43) Pub. Date: Sep. 3, 2026

(54) FILM FORMING METHOD AND FILM FORMING APPARATUS

(71) Applicant: Tokyo Electron Limited, Tokyo (JP)

(72) Inventors: Takamichi KIKUCHI, Yamanashi (JP); Yoshikazu IDENO, Yamanashi (JP); Daisuke FUDAUCHI, Yamanashi (JP)

(21) Appl. No.: 19/656,360

(22) Filed: Apr. 23, 2026

Related U.S. Application Data
(63) Continuation of application No. PCT/JP2024/036814, filed on Oct. 16, 2024.

(30) Foreign Application Priority Data
Oct. 25, 2023 (JP) 2023-182987

(51) Int. Cl. H10P 14/60; C23C 16/44; C23C 16/455; C23C 16/52; H10P 14/694

(52) U.S. Cl. CPC H10P 14/6339; C23C 16/4412; C23C 16/45523; C23C 16/45565; C23C 16/4557; C23C 16/52; H10P 14/6532; H10P 14/694

(57) ABSTRACT

A film forming method includes (A) forming a first nitride film on a substrate, without supplying a source gas to the substrate, by decomposing at least a portion of a reaction product of the source gas and a nitriding gas and depositing the portion of the reaction product on the substrate in a state in which the reaction product has already been deposited on a member inside a processing chamber, the source gas containing an element to be nitrided and a halogen element. Decomposing at least the portion of the reaction product includes generating plasma inside the processing chamber and causing the plasma to impinge on the reaction product.

### CROSS-REFERENCE TO RELATED APPLICATIONS

This application is a continuation of International Application No. PCT/JP2024/036814, filed on Oct. 16, 2024 and designating the U.S., which claims priority to Japanese Patent Application No. 2023-182987, filed on Oct. 25, 2023. The contents of these applications are incorporated herein by reference in their entirety.

### TECHNICAL FIELD

The present disclosure relates to a film forming method and a film forming apparatus.

### BACKGROUND ART

A film forming method described in Japanese Laid-Open Patent Publication No. 2018-80349 forms a TiN film on a substrate by an atomic layer deposition (ALD) method. Specifically, the TiN film is formed on the substrate by alternately supplying TiCl₄ gas and NH₃ gas to the substrate.

### SUMMARY

A film forming method according to one aspect of the present disclosure includes (A) forming a first nitride film on a substrate, without supplying a source gas to the substrate, by decomposing at least a portion of a reaction product of the source gas and a nitriding gas and depositing the portion of the reaction product on the substrate in a state in which the reaction product has already been deposited on a member inside a processing chamber, the source gas containing an element to be nitrided and a halogen element. Decomposing at least the portion of the reaction product includes generating plasma inside the processing chamber and causing the plasma to impinge on the reaction product.

### BRIEF DESCRIPTION OF THE DRAWINGS

FIG. 1 is a plan view illustrating a film forming apparatus according to an embodiment;

FIG. 2 is a flowchart illustrating an example of a method of forming a second nitride film;

FIG. 3 is a timing chart illustrating the example of the method of forming the second nitride film;

FIG. 4 is a diagram illustrating an example of film forming conditions of the second nitride film;

FIG. 5 is a flowchart illustrating an example of a method of forming a first nitride film;

FIG. 6 is a timing chart illustrating the example of the method of forming the first nitride film;

FIG. 7 is a diagram illustrating an example of film forming conditions of the first nitride film;

FIG. 8 is a diagram illustrating an example of the chlorine content in the first nitride film and an example of the chlorine content in the second nitride film;

FIG. 9 is a flowchart illustrating a film forming method according to an embodiment;

FIG. 10 is a diagram illustrating the chlorine content at an interface between a substrate and a nitride film according to each of an Example and a Comparative Example;

FIG. 11 is a diagram illustrating film forming conditions (of the first nitride film) in S301 of FIG. 10; and

FIG. 12 is a diagram illustrating film forming conditions (of the second nitride film) in S302 of FIG. 10.

### DETAILED DESCRIPTION

Embodiments of the present disclosure will be described below with reference to the accompanying drawings. In the drawings, the same or corresponding components are denoted by the same reference numerals, and redundant descriptions may be omitted.

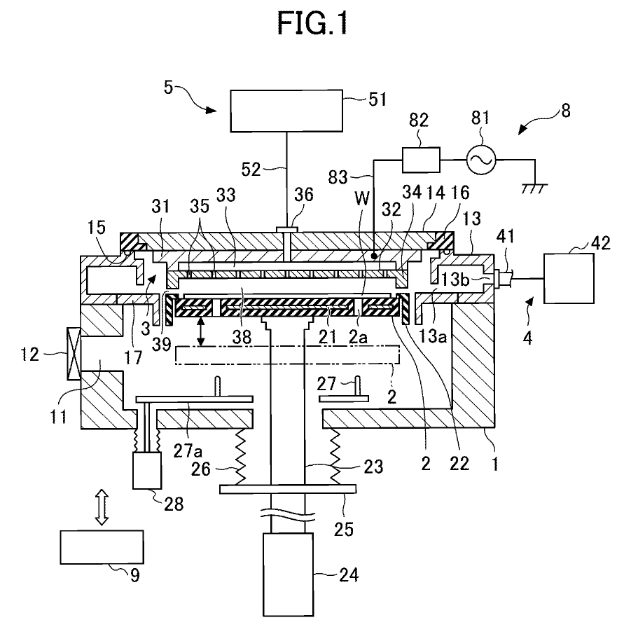

A film forming apparatus according to an embodiment will be described with reference to FIG. 1. The film forming apparatus includes a processing chamber 1, a holder 2, a showerhead 3, a gas exhaust 4, a gas supply 5, a plasma generator 8, a controller 9, and the like.

The processing chamber 1 is formed of a metal such as aluminum, and has substantially a cylindrical shape. The processing chamber 1 accommodates a substrate W. The substrate W includes, for example, a semiconductor substrate. The semiconductor substrate is, for example, a silicon wafer or a compound semiconductor wafer. The compound semiconductor wafer is, for example, a GaAs wafer, a SiC wafer, a GaN wafer, or an InP wafer. The substrate W may include various functional films formed on the semiconductor substrate. The functional films include at least one of a conductive film or an insulating film.

A loading and unloading port 11 for loading and unloading the substrate W by a transfer device (not illustrated) is formed in a side wall of the processing chamber 1. The loading and unloading port 11 is opened and closed by a gate valve 12. An annular exhaust duct 13 having a rectangular cross-sectional shape is disposed on the main body of the processing chamber 1. A slit 13a is formed along the inner peripheral surface of the exhaust duct 13. An exhaust port 13b is formed in the outer wall of the exhaust duct 13. A ceiling 14 is disposed on the upper surface of the exhaust duct 13 to cover an upper opening of the processing chamber 1 via an insulator member 16. A gap between the exhaust duct 13 and the insulator member 16 is airtightly sealed by a seal ring 15. A partitioning member 17 partitions the interior of the processing chamber 1 into an upper section and a lower section when the holder 2 (and a cover member 22) is lifted to a processing position described later.

The holder 2 supports the substrate W in the processing chamber 1. The holder 2 is, for example, a stage and horizontally supports the substrate W. The holder 2 is formed in a disc shape having a size corresponding to the substrate W, and is supported by a support member 23. The holder 2 is formed of a ceramic material such as AlN, or a metal material such as aluminum or a nickel alloy. A heater 21 for heating the substrate W is embedded in the holder 2. The heater 21 is supplied with power from a heater power source (not illustrated) and generates heat. By controlling the output of the heater 21 according to a temperature signal of a thermocouple (not illustrated) disposed in the vicinity of the upper surface of the holder 2, the substrate W is controlled to a predetermined temperature. The cover member 22 formed of a ceramic such as alumina is provided so as to cover an outer peripheral region of the upper surface and a side surface of the holder 2.

The support member 23 supporting the holder 2 is provided on the bottom surface of the holder 2. The support member 23 extends from the center of the bottom surface of the holder 2 to the lower side of the processing chamber 1 through a hole formed in a bottom wall of the processing chamber 1, and the lower end of the support member 23 is connected to a lifting and lowering mechanism 24. The holder 2 is lifted and lowered by the lifting and lowering mechanism 24 via the support member 23 between a processing position illustrated in FIG. 1 and a transfer position at which the substrate W can be transferred, indicated by a two-dot dash line below the processing position. A flange 25 is attached to the support member 23 below the processing chamber 1. A bellows 26 is provided between the bottom surface of the processing chamber 1 and the flange 25. The bellows 26 separates the atmosphere in the processing chamber 1 from the outside air and expands and contracts according to the lifting and lowering movement of the holder 2.

Three wafer support pins 27 (only two of which are illustrated) are provided in the vicinity of the bottom surface of the processing chamber 1 so as to protrude upward from a lifting and lowering plate 27a. The wafer support pins 27 are lifted and lowered via the lifting and lowering plate 27a by a lifting and lowering mechanism 28 provided below the processing chamber 1. The wafer support pins 27 are inserted into through-holes 2a provided in the holder 2 at the transfer position so as to be projected and retracted with respect to the upper surface of the holder 2. By lifting and lowering the wafer support pins 27, the substrate W is transferred between a transfer mechanism (not illustrated) and the holder 2.

The showerhead 3 supplies various processing gases into the processing chamber 1 in the form of a shower. The showerhead 3 is formed of a metal, is disposed to face the holder 2, and has a diameter substantially equal to that of the holder 2. The showerhead 3 includes a main body 31 and a shower plate 32. The main body 31 is fixed to the ceiling 14 of the processing chamber 1. The shower plate 32 is connected under the main body 31. A gas diffusion space 33 is formed between the main body 31 and the shower plate 32. A gas introduction hole 36 is provided in the gas diffusion space 33 so as to penetrate through the center of the ceiling 14 of the processing chamber 1 and the center of the main body 31. An annular projection 34 projecting downward is formed on the peripheral edge of the shower plate 32. Gas discharge holes 35 are formed in a flat surface of the shower plate 32 located inward of the annular projection 34. With the holder 2 located at the processing position, a processing space 38 is formed between the holder 2 and the shower plate 32 and the annular projection 34 is close to the upper surface of the cover member 22, thereby forming an annular gap 39.

The gas exhaust 4 exhausts gas from the inside of the processing chamber 1 to the outside. The gas exhaust 4 includes an exhaust pipe 41 connected to the exhaust port 13b, and an exhaust mechanism 42 connected to the exhaust pipe 41. The exhaust mechanism 42 includes a vacuum pump, a pressure control valve, and the like. During processing, the gas inside the processing chamber 1 passes through the slit 13a to reach the exhaust duct 13, and the gas is exhausted from the exhaust duct 13 through the exhaust pipe 41 by the exhaust mechanism 42.

The gas supply 5 supplies various gases to the showerhead 3 so as to supply the various gases from the showerhead 3 toward the holder 2. The gas supply 5 includes a gas source 51 and a gas line 52. The gas source 51 includes, for example, a source that supplies the various gases, a mass flow controller, and a valve (none of which is illustrated). The various gases are introduced from the gas source 51 into the gas diffusion space 33 through the gas line 52 and the gas introduction hole 36.

The film forming apparatus is, for example, a capacitively coupled plasma apparatus in which the holder 2 functions as a lower electrode and the showerhead 3 functions as an upper electrode. The holder 2 is grounded via a capacitor (not illustrated). However, the holder 2 may be grounded without, for example, a capacitor, or may be grounded via a circuit in which a capacitor and a coil are combined. The showerhead 3 is electrically connected to the plasma generator 8.

The plasma generator 8 generates plasma inside the processing chamber 1. The plasma generator 8 includes an RF power source 81, a matching device 82, and a feed line 83. The RF power source 81 is a power source that generates high-frequency power (hereinafter also referred to as “RF power”). The RF power has a frequency suitable for generation of plasma. The frequency of the RF power is, for example, a frequency within a range of 450 kHz in the low frequency band to 2.45 GHz in the microwave band. The RF power source 81 is electrically connected to the main body 31 of the showerhead 3 via the matching device 82 and the feed line 83. The matching device 82 includes a circuit for matching load impedance with the internal impedance of the RF power source 81. The feed line 83 supplies the RF power to the showerhead 3.

Although the plasma generator 8 has been described as supplying the RF power to the showerhead 3 functioning as the upper electrode, the configuration is not limited thereto. The plasma generator 8 may be configured to supply the RF power to the holder 2 functioning as the lower electrode. The plasma generator 8 is not limited to a plasma generator configured to generate capacitively coupled plasma, but may be a plasma generator configured to generate different plasma, such as inductively coupled plasma or the like.

The controller 9 is, for example, a computer, and includes a central processing unit (CPU), a random access memory (RAM), a read only memory (ROM), an auxiliary memory, and the like. The CPU operates based on a program stored in the ROM or the auxiliary memory, and controls the operation of the film forming apparatus.

The controller 9 includes an electronic circuit such as a CPU, a field programmable gate array (FPGA), or an application specific integrated circuit (ASIC). The controller 9 performs various control operations described in the present specification by executing instruction codes stored in a memory or by being designed as a circuit for a special application.

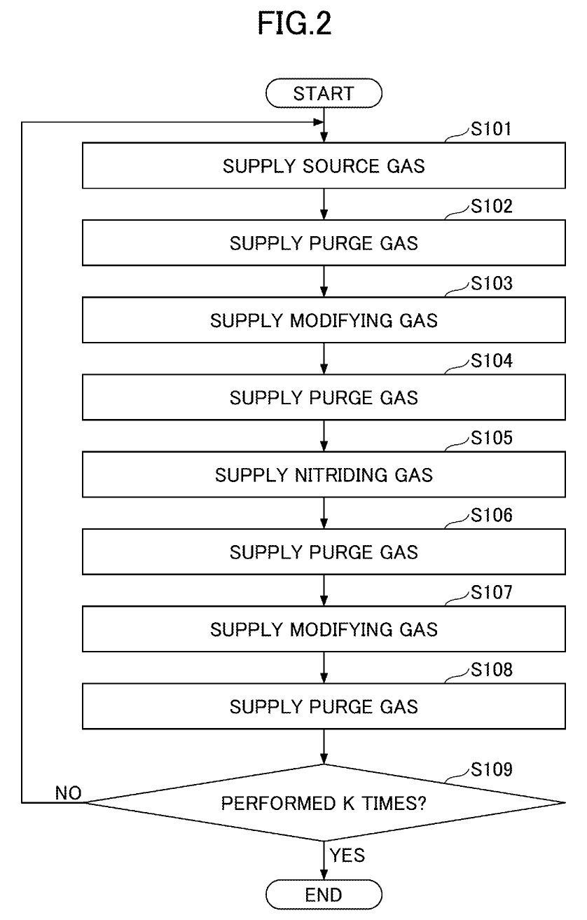

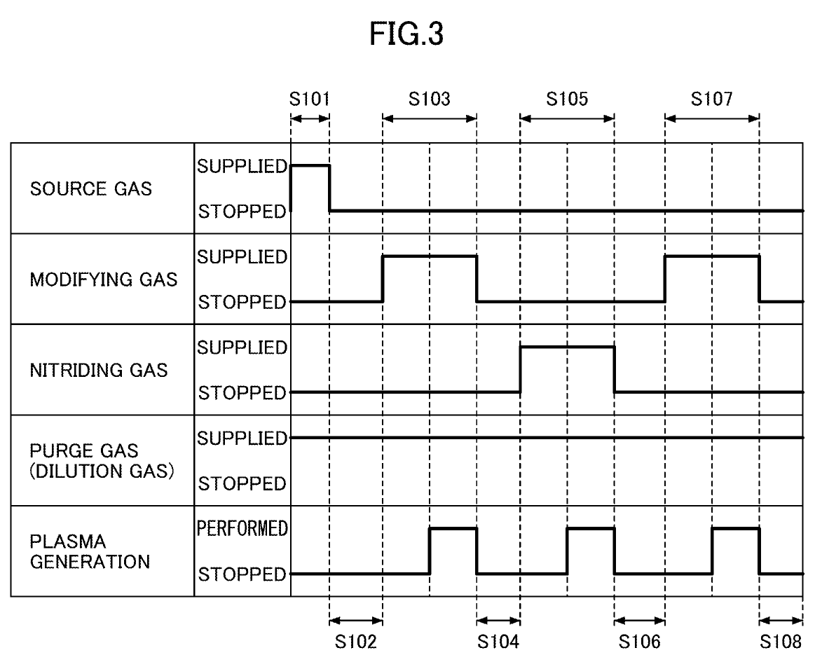

Next, a method of forming a second nitride film will be described with reference to FIGS. 2 and 3. When the substrate W is loaded from the outside to the inside of the processing chamber 1 by the transfer apparatus (not illustrated), the controller 9 performs steps S101 to S109. In steps S101 to S108, the temperature of the holder 2, that is, the temperature of the substrate W is, for example, in a range of 300° C. to 500° C., the temperature of the showerhead 3 is, for example, in a range of 300° C. to 500° C., and the pressure inside the processing chamber 1 is, for example, in a range of 100 Pa to 600 Pa. The method of forming the second nitride film does not necessarily include all of steps S101 to S109. Further, the method of forming the second nitride film may include a step other than steps S101 to S109.

In step S101, the gas supply 5 supplies a source gas to the substrate W via the showerhead 3 while the gas exhaust 4 exhausts gas from the inside to the outside of the processing chamber 1. The source gas contains an element X to be nitrided and a halogen element. The source gas is, for example, TiCl₄ gas. By supplying the source gas to the substrate W, a source-containing layer containing the element X can be formed on the substrate W. The element X is, for example, Ti. The source-containing layer may contain the halogen element in addition to the element X. The halogen element is, for example, Cl. The source gas may be supplied together with a dilution gas. The dilution gas is, for example, Ar gas or N₂ gas.

The source gas is TiCl₄ gas in the present embodiment, but is not limited to TiCl₄ gas. The source gas may be WCl₆ gas, VCl₄ gas, AlCl₃ gas, MoCl₅ gas, SnCl₄ gas, or HfCl₄ gas. That is, the element X may be W, V, Al, Mo, Sn, or Hf. The element X may be a semiconductor element, and may be, for example, Si or Ge. That is, the source gas may be a silicon halide gas or a germanium halide gas. The silicon halide gas is, for example, SiCl₄ gas, SiHCl₃ gas, SiH₂Cl₂ gas, SiH₃Cl gas, Si₂Cl₆ gas, Si₂HCl₅ gas, SiH₂I₂ gas, SiCl₃CH₃ gas, or the like. The germanium halide gas is, for example, GeCl₄ gas.

In step S102, the gas supply 5 supplies a purge gas to the substrate W via the showerhead 3 while the gas exhaust 4 exhausts gas from the inside to the outside of the processing chamber 1. Thus, the gas remaining inside the processing chamber 1 can be replaced with the purge gas. The purge gas is, for example, Ar gas or N₂ gas.

In step S103, the gas supply 5 supplies a modifying gas to the substrate W via the showerhead 3 while the gas exhaust 4 exhausts gas from the inside to the outside of the processing chamber 1. The modifying gas is, for example, H₂ gas or N₂ gas. The modifying gas may be a mixed gas of H₂ gas and N₂ gas. The modifying gas may be supplied together with a dilution gas. The dilution gas is, for example, Ar gas. By supplying the modifying gas to the substrate W, the source-containing layer can be modified. Modifying the source-containing layer includes, for example, removing the halogen element contained in the source-containing layer. By removing the halogen element, the source-containing layer can be activated, and nitridation of the source-containing layer can be facilitated. In step S103, the plasma generator 8 may form the modifying gas into plasma so as to facilitate the modification of the source-containing layer.

Similar to step S102, in step S104, the gas supply 5 supplies a purge gas to the substrate W via the showerhead 3 while the gas exhaust 4 exhausts gas from the inside to the outside of the processing chamber 1. Thus, the gas remaining in the processing chamber 1 is replaced with the purge gas. The purge gas is, for example, Ar gas or N₂ gas.

In step S105, the gas supply 5 supplies a nitriding gas to the substrate W via the showerhead 3 while the gas exhaust 4 exhausts gas from the inside to the outside of the processing chamber 1. The nitriding gas is, for example, NH₃ gas or N₂ gas. The nitriding gas may be supplied together with a dilution gas. The dilution gas is, for example, Ar gas. By supplying the nitriding gas to the substrate W, the source-containing layer can be nitrided. In step S105, the plasma generator 8 may form the nitriding gas into plasma so as to facilitate the nitridation of the source-containing layer.

Similar to step S102, in step S106, the gas supply 5 supplies a purge gas to the substrate W via the showerhead 3 while the gas exhaust 4 exhausts gas from the inside to the outside of the processing chamber 1. Thus, the gas remaining in the processing chamber 1 is replaced with the purge gas. The purge gas is, for example, Ar gas or N₂ gas.

Similar to step S103, in step S107, the gas supply 5 supplies the modifying gas to the substrate W via the showerhead 3 while the gas exhaust 4 exhausts gas from the inside to the outside of the processing chamber 1. Thus, the nitrided source-containing layer can be modified. Modifying the nitrided source-containing layer includes, for example, removing the halogen element contained in the source-containing layer. Further, modifying the nitrided source-containing layer includes removing unnecessary reaction products (for example, NH₄Cl) generated by the nitridation of the source-containing layer. The modifying gas may be supplied together with a dilution gas. In step S107, the plasma generator 8 may form the modifying gas into plasma so as to facilitate the modification of the nitrided source-containing layer.

The method of forming the second nitride film may include either step S103 or step S107.

Similar to step S102, in step S108, the gas supply 5 supplies a purge gas to the substrate W via the showerhead 3 while the gas exhaust 4 exhausts gas from the inside to the outside of the processing chamber 1. Thus, the gas remaining in the processing chamber 1 is replaced with the purge gas. The purge gas is, for example, Ar gas or N₂ gas.

In step S109, the controller 9 determines whether steps S101 to S108 are performed a set number of times (K times). K is an integer of 1 or more. If the number of times steps S101 to S108 are performed does not reach K (NO in step S109), the controller 9 performs step S101 and the subsequent steps again. Conversely, if the number of times steps S101 to S108 are performed reaches K (YES in step S109), the controller 9 ends the current processing. Thereafter, the transfer device (not illustrated) unloads the substrate W from the inside to the outside of the processing chamber 1.

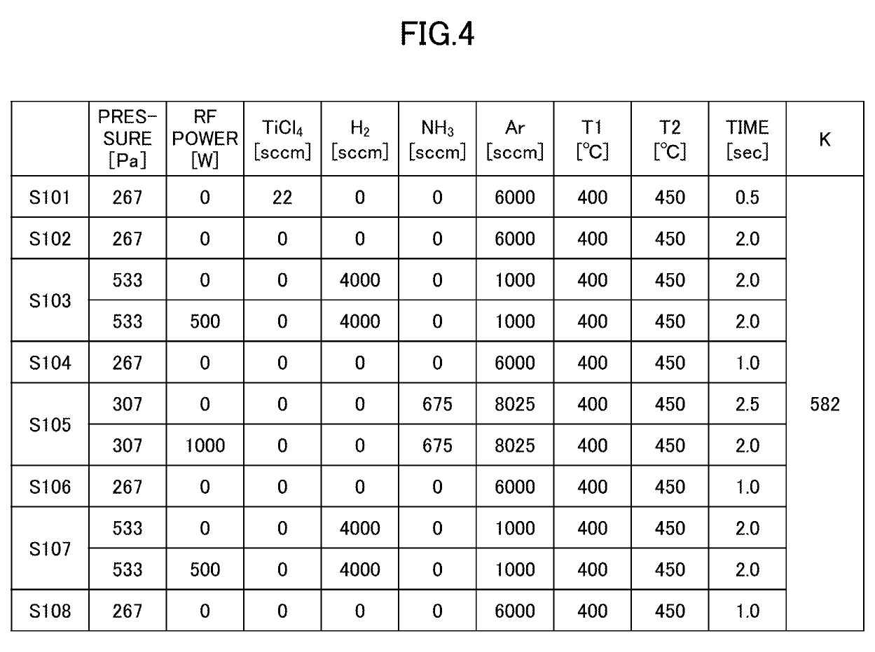

FIG. 4 illustrates an example of film forming conditions of the second nitride film. In FIG. 4, RF power of 0 W means that the plasma generator 8 does not form gas inside the processing chamber 1 into plasma, and RF power of 500 W or 1,000 W means that the plasma generator 8 forms gas inside the processing chamber 1 into plasma. In FIG. 4, TiCl₄ is the source gas, H₂ gas is the modifying gas, NH₃ gas is the nitriding gas, and Ar gas is a purge gas or a dilution gas. In FIG. 4, T1 is the temperature of the holder 2, that is, the temperature of the substrate W, and T2 is the temperature of the showerhead 3.

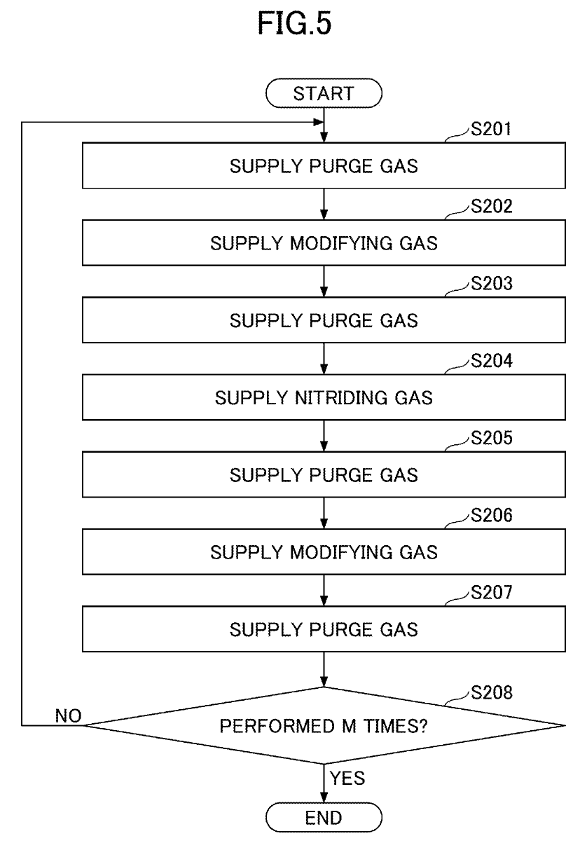

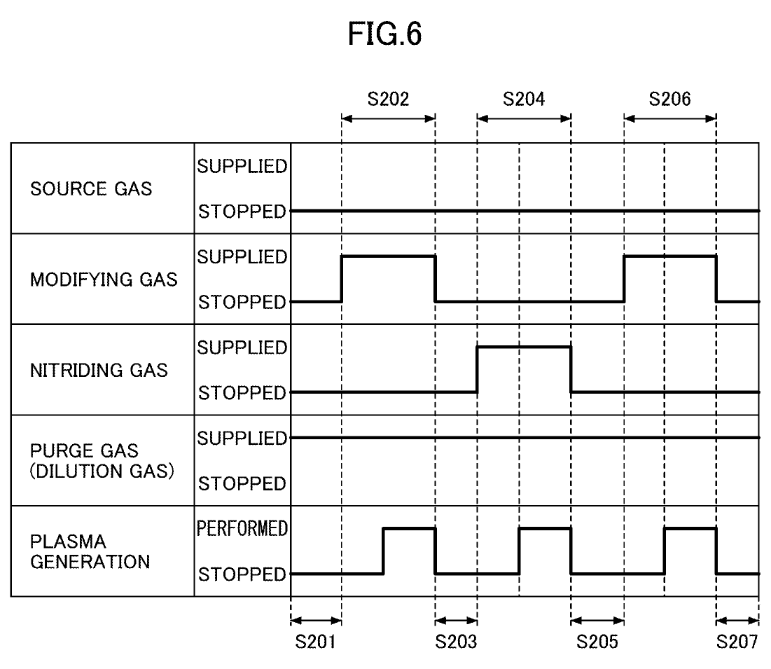

Next, an example of a method of forming a first nitride film will be described with reference to FIGS. 5 and 6. When the substrate W is loaded from the outside to the inside of the processing chamber 1 by the transfer device (not illustrated), the controller 9 performs steps S201 to S208. The method of forming the first nitride film is performed in the same manner as the method of forming the second nitride film, except that there is no step corresponding to step S101, that is, the source gas is not supplied to the substrate W. Because steps S201 to S207 are performed in the same manner as steps S102 to S108, a detailed description thereof will be omitted. In steps S201 to S207, the temperature of the holder 2, that is, the temperature of the substrate W is, for example, in a range of 300° C. to 500° C., the temperature of the showerhead 3 is, for example, in a range of 300° C. to 500° C., and the pressure inside the processing chamber 1 is, for example, in a range of 100 Pa to 600 Pa.

In step S208, the controller 9 determines whether steps S201 to S207 are performed a set number of times (M times). M is an integer of 1 or more. If the number of times steps S201 to S207 are performed does not reach M (NO in step S208), the controller 9 performs step S201 and the subsequent steps again. Conversely, if the number of times steps S201 to S207 are performed reaches M (YES in step S208), the controller 9 ends the current processing. Thereafter, the transfer device (not illustrated) unloads the substrate W from the inside to the outside of the processing chamber 1. The method of forming the first nitride film does not necessarily include all of steps S201 to S208. Further, the method of forming the first nitride film may include a step other than steps S201 to S208.

The method of forming the first nitride film includes forming the first nitride film on the substrate W without supplying the source gas to the substrate W by decomposing at least a portion of a reaction product of the source gas and the nitriding gas and depositing the portion of the reaction product on the substrate W in a state in which the reaction product has already been deposited on a member inside the processing chamber 1. When the first nitride film is formed, the nitriding gas may be supplied or is not necessarily supplied, as long as the source gas is not supplied.

Decomposing at least the portion of the reaction product includes generating plasma inside the processing chamber 1 and causing the generated plasma to impinge on the reaction product. That is, decomposing at least the portion of the reaction product includes plasma sputtering. The member is not particularly limited and may be any member provided inside the processing chamber 1, and is, for example, the showerhead 3.

In the method of forming the first nitride film, the first nitride film is formed on the substrate W without supplying the source gas to the substrate W. Because the first nitride film does not use the source gas containing the halogen element, the content of the halogen element can be reduced. According to the present embodiment, even if the temperature of the substrate W when the first nitride film is formed is 400° C. or less, the content of the halogen element in the first nitride film can be reduced to 1.0 × 10¹⁹ atoms/cm³ or less. The content of the halogen element is measured by secondary ion mass spectrometry (SIMS) at a position 5 nm deep from the surface of the first nitride film. The content of the halogen element in the first nitride film is preferably 2.0 × 10¹⁸ atoms/cm³ or less. The lower the content of the halogen element, the better the film quality (e.g., film density).

The reaction product is deposited on the member inside the processing chamber 1 by performing, for example, the method of forming the second nitride film illustrated in FIGS. 2 and 3 before the first nitride film is formed. Alternatively, the reaction product may be deposited on the member inside the processing chamber 1 by performing the method of forming the second nitride film illustrated in FIGS. 2 and 3 in a state in which the substrate W is not present inside the processing chamber 1 before the first nitride film is formed. After the reaction product is deposited on the member inside the processing chamber 1, the reaction product releases the halogen element by being exposed to gas inside the processing chamber 1. As a result, the content of the halogen element in the reaction product can be reduced before the first nitride film is formed.

The reaction product is preferably modified by being exposed to H₂ gas while the showerhead 3 is heated to 300° C. to 500° C. before the first nitride film is formed. The reaction product is more preferably modified by being exposed to H₂ gas formed into plasma, while the showerhead 3 is heated to 300° C .to 500° C. before the first nitride film is formed. The content of the halogen element in the reaction product can be reduced before the first nitride film is formed.

The plasma caused to impinge on the reaction product when the first nitride film is formed is preferably generated while at least one of Ar gas, H₂ gas, or NH₃ gas is supplied to the substrate W in a state in which the pressure inside the processing chamber 1 is 600 Pa or less and high-frequency power (RF power) applied to a gas inside the processing chamber 1 is 500 W or more.

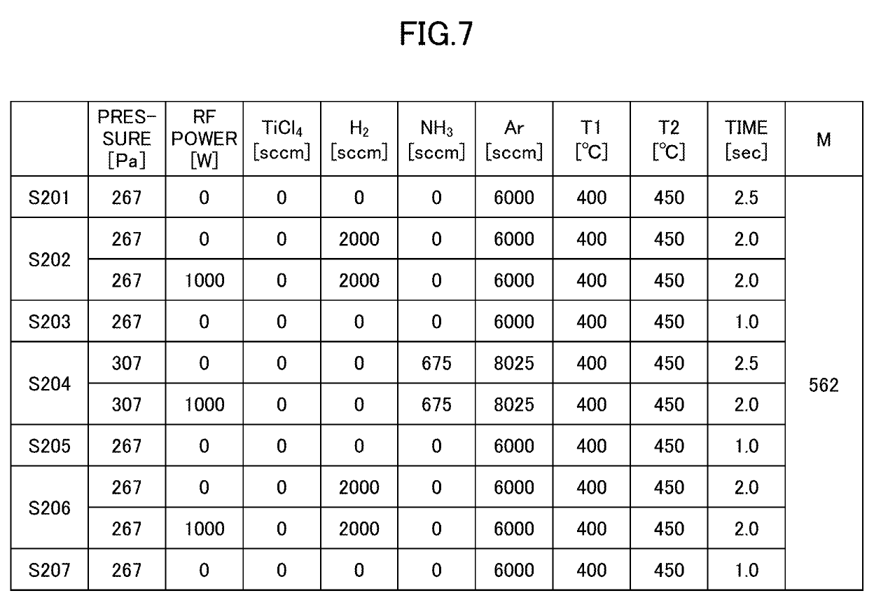

FIG. 7 illustrates an example of film forming conditions of the first nitride film. In FIG. 7, RF power of 0 W means that the plasma generator 8 does not form gas inside the processing chamber 1 into plasma, and RF power of 1,000 W means that the plasma generator 8 forms gas inside the processing chamber 1 into plasma. In FIG. 7, TiCl₄ is the source gas, H₂ gas is the modifying gas, NH₃ gas is the nitriding gas, and Ar gas is a purge gas or a dilution gas. In FIG. 7, T1 is the temperature of the holder 2, that is, the temperature of the substrate W, and T2 is the temperature of the showerhead 3.

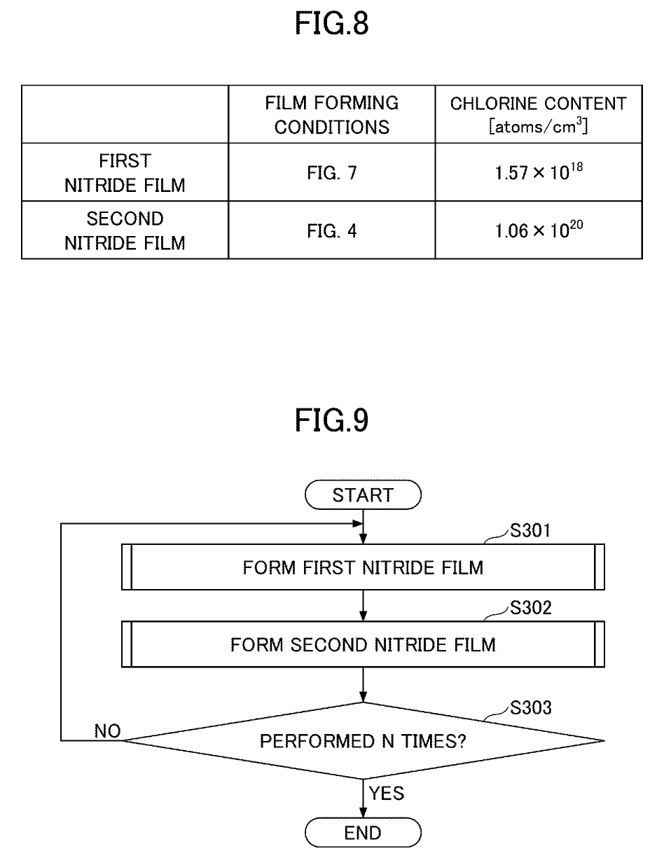

FIG. 8 illustrates an example of the chlorine content in the second nitride film and an example of the chlorine content in the first nitride film. The contents of chlorine were measured by secondary ion mass spectrometry (SIMS) at a position 5 nm deep from the surface of the second nitride film and at a position 5 nm deep from the surface of the first nitride film. As can be seen from FIG. 8, the chlorine content in the first nitride film was less than the chlorine content in the second nitride film and was 1.0 × 10¹⁹ atoms/cm³ or less.

Next, a film forming method according to an embodiment will be described with reference to FIG. 9. When the substrate W is loaded from the outside to the inside of the processing chamber 1 by the transfer device (not illustrated), the controller 9 performs steps S301 to S303. In step S301, the first nitride film is formed. The method of forming the first nitride film is as described above. In step S302, the second nitride film is formed. The method of forming the second nitride film is as described above.

In step S303, the controller 9 determines whether steps S301 to S303 are performed a set number of times (N times). N is an integer of 1 or more. If the number of times steps S301 to S303 are performed does not reach N (NO in step S303), the controller 9 performs step S301 and the subsequent step again. Conversely, if the number of times steps S301 to S303 are performed reaches N (YES in step S303), the controller 9 ends the current processing. Thereafter, the transfer device (not illustrated) unloads the substrate W from the inside to the outside of the processing chamber 1.

Although step S301 is performed before step S302 in the present embodiment, step S301 may be performed after step S302. In a case where N is an integer of 2 or more, step S301 and step S302 of the film forming method are alternately repeated a plurality of times. The ratio of the thickness of the first nitride film to the thickness of the second nitride film may be changed between when steps S301 and S302 are performed for the m-th time and when steps S301 and S302 are performed for the n-th time (n is an integer greater than m and less than or equal to N).

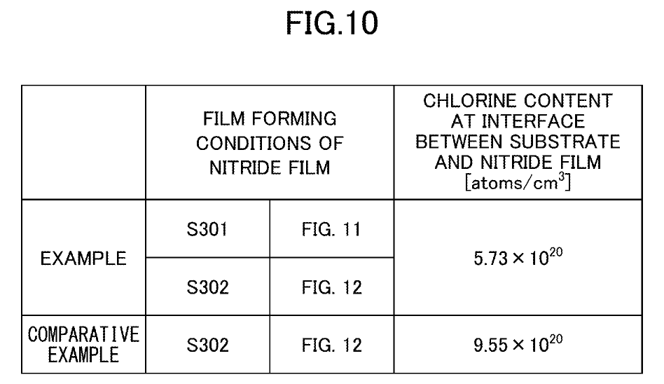

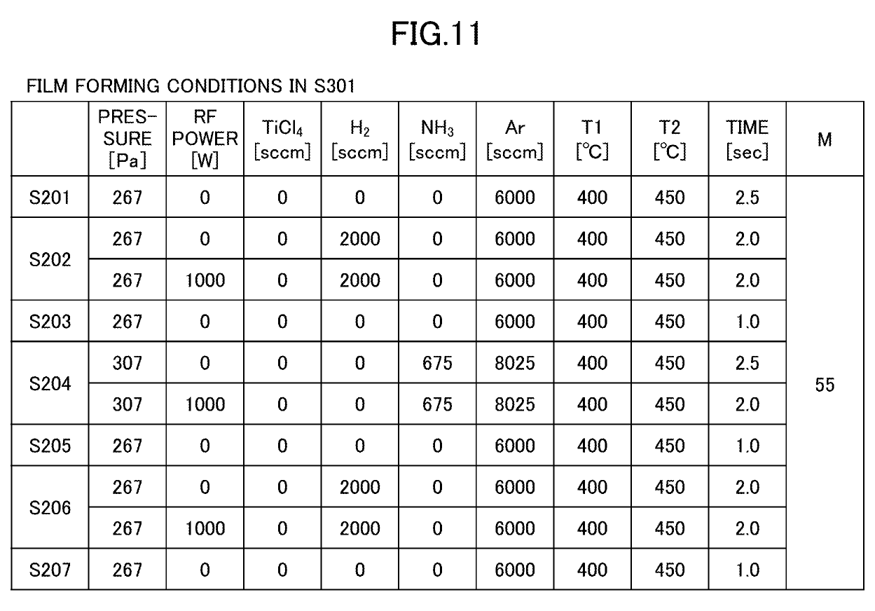

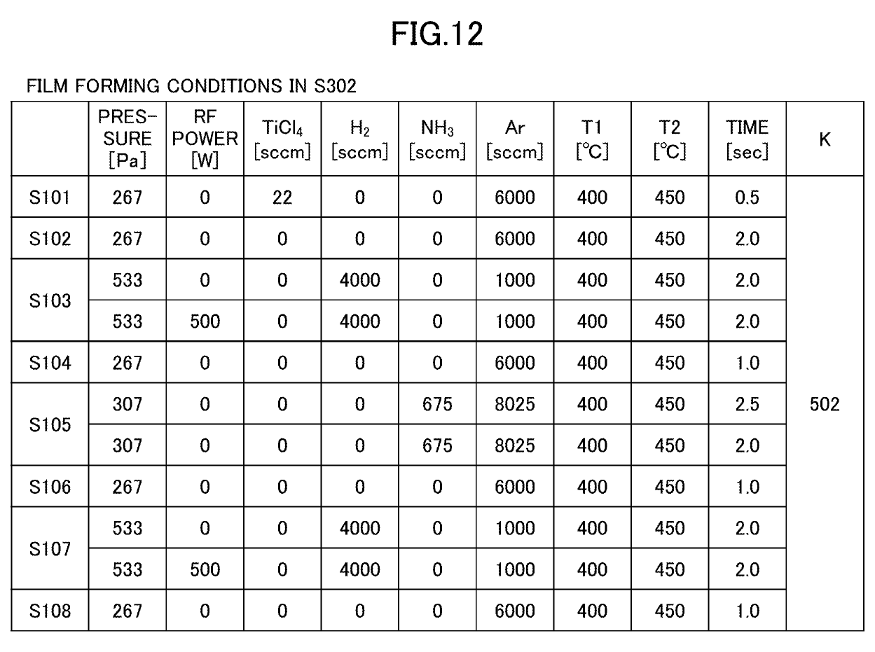

Next, the chlorine content at an interface between a substrate and a nitride film according to each of an Example and a Comparative Example will be described with reference to FIG. 10. As illustrated in FIG. 10, in the Example, steps S301 and S302 were performed once each in this order, and in the Comparative Example, only step S302 was performed. FIG. 11 illustrates film forming conditions in step S301. FIG. 12 illustrates film forming conditions in step S302. As illustrated in FIG. 10, unlike the Comparative Example, the first nitride film was formed before the second nitride film was formed in the Example, and thus the chlorine content at the interface between a substrate and a nitride film was able to be reduced.

Although the film forming method and the film forming apparatus according to the embodiments of the present disclosure have been described above, the present disclosure is not limited to the above-described embodiments. Various changes, modifications, substitutions, additions, deletions, and combinations are possible within the scope of the claims. These also naturally fall within the technical scope of the present disclosure.

According to one aspect of the present disclosure, the content of a halogen element in a nitride film can be reduced.

What is claimed is:

1. A film forming method comprising:
(A) forming a first nitride film on a substrate, without supplying a source gas to the substrate, by decomposing at least a portion of a reaction product of the source gas and a nitriding gas and depositing the portion of the reaction product on the substrate in a state in which the reaction product has already been deposited on a member inside a processing chamber, the source gas containing an element to be nitrided and a halogen element, wherein
decomposing at least the portion of the reaction product includes generating plasma inside the processing chamber and causing the plasma to impinge on the reaction product.

2. The film forming method according to claim 1, further comprising:
(B) forming a second nitride film on the substrate by supplying the source gas and the nitriding gas to the substrate, wherein
the (A) is performed before the (B).

3. The film forming method according to claim 1, further comprising:
(B) forming a second nitride film on the substrate by supplying the source gas and the nitriding gas to the substrate, wherein
the (A) is performed after the (B).

4. The film forming method according to claim 2, wherein the (A) and the (B) are alternately repeated a plurality of times.

5. The film forming method according to claim 4, wherein a ratio of a thickness of the first nitride film to a thickness of the second nitride film is changed between when the (A) and the (B) are performed for an m-th time and when the (A) and the (B) are performed for an n-th time, where n is an integer greater than m.

6. The film forming method according to claim 2, wherein the (B) includes modifying the second nitride film by supplying at least one of H₂ gas or N₂ gas to the substrate.

7. The film forming method according to claim 1, wherein
the member is a showerhead configured to discharge the source gas, and
the reaction product is modified by being exposed to H₂ gas while the showerhead is heated to 300° C. to 500° C. before the (A).

8. The film forming method according to claim 7, wherein the reaction product is modified by being exposed to H₂ gas formed into plasma, while the showerhead is heated to 300° C. to 500° C. before the (A).

9. The film forming method according to claim 1, wherein, in the (A), the plasma caused to impinge on the reaction product is generated while at least one of Ar gas, H₂ gas, or NH₃ gas is supplied to the substrate in a state in which pressure inside the processing chamber is 600 Pa or less and high-frequency power applied to a gas inside the processing chamber is 500 W or more.

10. A film forming apparatus comprising:
the processing chamber;
a holder configured to hold the substrate inside the processing chamber;
a showerhead disposed to face the holder;
a gas supply configured to supply a gas to the showerhead so as to supply the gas from the showerhead toward the holder;
a gas exhaust configured to exhaust a gas from inside the processing chamber;
a plasma generator configured to generate the plasma inside the processing chamber; and
a controller configured to control the gas supply, the gas exhaust, and the plasma generator and perform the film forming method of claim 1.
